(19) United States
(12) Patent Application Publication
(10) Pub. No.: US 2023/0090736 A1
(43) Pub. Date: Mar. 23, 2023

(54) POLYPHENYLENE ETHER RESIN MODIFIED WITH TWO AMINO FUNCTIONAL GROUPS, METHOD FOR PRODUCING THE SAME, AND SUBSTRATE MATERIAL FOR CIRCUIT BOARD

(71) Applicant: NAN YA PLASTICS CORPORATION, TAIPEI (TW)

(72) Inventors: TE-CHAO LIAO, TAIPEI (TW); HUNG-YI CHANG, TAIPEI (TW); YU-TING LIU, New Taipei City (TW); CHUNG-YU CHEN, TAIPEI (TW); CHIA-RUEY TSAI, TAIPEI (TW); JUNG-TSU WU, TAIPEI (TW); CHIEN-KAI WEI, TAIPEI (TW)

(21) Appl. No.: 17/887,525

(22) Filed: Aug. 15, 2022

(30) Foreign Application Priority Data
Sep. 13, 2021 (TW) 110133957

(51) Int. Cl. C08G 65/48; H05K 1/03

(52) U.S. Cl. CPC C08G 65/48; H05K 1/0346

(57) ABSTRACT

A polyphenylene ether resin modified with two amino functional groups, a method for producing the same, and a substrate material for a circuit board are provided. The polyphenylene ether resin modified with the two amino functional groups has a structural formula as follows:

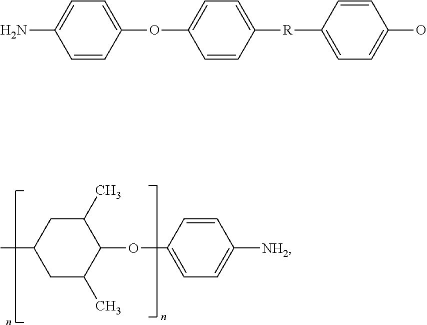

in which R represents a chemical group that is located between two hydroxyphenyl functional groups of a bisphenol compound, and n is an integer between 3 and 25, inclusive.

### CROSS-REFERENCE TO RELATED PATENT APPLICATION

This application claims the benefit of priority to Taiwan Patent Application No. 110133957, filed on Sep. 13, 2021. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a polyphenylene ether resin modified with two amino functional groups, and more particularly to a polyphenylene ether resin modified with the two amino functional groups, a method for producing the same, and a substrate material for a circuit board.

### BACKGROUND OF THE DISCLOSURE

Most conventional epoxy resin hardeners are bisamine epoxy resin hardeners, which have high reactivity, great reliability, and great stability.

However, the conventional epoxy resin hardeners have a high dielectric constant and a high dielectric dissipation factor. Therefore, the conventional epoxy resin hardeners, when being applied to the substrate material of a circuit board (e.g., a high-frequency circuit board using the 5G technology), cannot effectively improve electrical characteristics of the circuit board.

### SUMMARY OF THE DISCLOSURE

In response to the above-referenced technical inadequacies, the present disclosure provides a polyphenylene ether resin modified with two amino functional groups, a method for producing the same, and a substrate material for a circuit board.

In one aspect, the present disclosure provides a method for producing a polyphenylene ether resin. The method includes: providing a high molecular mass polyphenylene ether resin material that has a first number average molecular mass, performing a cracking process, performing a nitration process, and performing a hydrogenation process. In the cracking process, the high molecular mass polyphenylene ether resin material is cracked to form a low molecular mass polyphenylene ether resin material that has a second number average molecular mass and is modified with a bisphenol functional group, and the second number average molecular mass is less than the first number average molecular mass. In the nitration process, the low molecular mass polyphenylene ether resin material is enabled to have a nitration reaction, so that two ends of a polymer chain of the low molecular mass polyphenylene ether resin material are respectively modified with two nitro functional groups. In the hydrogenation process, the low molecular mass polyphenylene ether resin material that contains the polymer chain having the two ends respectively modified with the two nitro functional groups is enabled to have a hydrogenation reaction, so as to form a low molecular mass polyphenylene ether resin material that contains a polymer chain having two ends respectively modified with two amino functional groups. The low molecular mass polyphenylene ether resin material which contains the polymer chain having the two ends respectively modified with the two amino functional groups has a structural formula as follows:

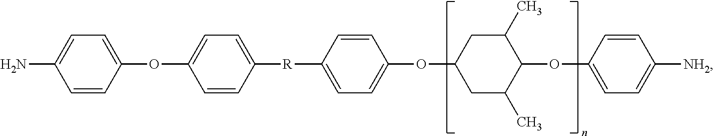

in which R represents a chemical group that is located between two hydroxyphenyl functional groups of a bisphenol compound, and n is an integer between 3 and 25, inclusive.

In certain embodiments, the first number average molecular mass of the high molecular mass (Mn) polyphenylene ether resin material is not less than 18,000, and the second number average molecular mass of the low molecular mass polyphenylene ether resin material is not greater than 12,000.

In certain embodiments, the cracking process includes reacting the bisphenol compound and the high molecular mass polyphenylene ether resin material having the first number average molecular mass in a presence of a peroxide so that the high molecular mass polyphenylene ether resin material is cracked to form the low molecular mass polyphenylene ether resin material having the second number average molecular mass. A side of the polymer chain of the low molecular mass polyphenylene ether resin material is modified with the bisphenol functional group.

In certain embodiments, the bisphenol compound is at least one material selected from a group consisting of 4,4′-biphenol, bisphenol A, bisphenol B, bisphenol S, bisphenol fluorene, 4,4′-ethylene bisphenol, 4,4′-dihydroxydiphenylmethane, 3,5,3′,5′-tetramethyl-4,4′-dihydroxybiphenyl, and 2,2-bis (4-hydroxy-3,5-dimethylphenyl) propane. A material type of the peroxide is at least one selected from a group consisting of azobisisobutyronitrile, benzyl peroxide, and dicumyl peroxide.

In certain embodiments, the nitration process includes carrying out the nitration reaction of a 4-halonitrobenzene material and the low molecular mass polyphenylene ether resin material that is cracked and modified with the bisphenol functional group in an alkaline environment so that the two ends of the polymer chain of the low molecular mass polyphenylene ether resin material are respectively modified with the two nitro functional groups.

In certain embodiments, the nitration process allows the nitration reaction of the low molecular mass polyphenylene ether resin material to be carried out in the alkaline environment, the alkaline environment having a pH value between 8 and 14.

In certain embodiments, the hydrogenation process includes performing the hydrogenation reaction on a hydrogenation solvent and the low molecular mass polyphenylene ether resin material that contains the polymer chain having the two ends respectively modified with the two nitro functional groups. A material type of the hydrogenation solvent is at least one material selected from a group consisting of dimethylacetamide, tetrahydrofuran, toluene, and isopropanol.

In certain embodiments, the hydrogenation solvent adopts the dimethylacetamide to carry out the hydrogenation reaction.

In another aspect, the present disclosure provides a polyphenylene ether resin modified with two amino functional groups, which is suitable for use as a substrate material for a circuit board. The polyphenylene ether resin modified with the two amino functional groups has a structural formula as follows:

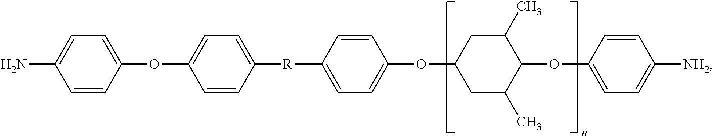

in which R represents a chemical group that is located between two hydroxyphenyl functional groups of a bisphenol compound, and n is an integer between 3 and 25, inclusive.

In yet another aspect, the present disclosure provides a substrate material for a circuit board. The substrate material for the circuit board has at least 20 wt % of the polyphenylene ether resin modified with the two amino functional groups mentioned above. The substrate material for the circuit board has a dielectric constant (Dk) that is between 3.5 and 4.0, a dielectric dissipation factor (Df) that is between 0.003 and 0.005, a glass transition temperature that is not less than 230° C., and a peel strength that is not less than 5 lb/in.

Therefore, in the polyphenylene ether resin modified with the two amino functional groups, the method for producing the same, and the substrate material for the circuit board provided by the present disclosure, by virtue of “providing a high molecular mass polyphenylene ether resin material that has a first number average molecular mass; performing a cracking process which includes: cracking the high molecular mass polyphenylene ether resin material to form a low molecular mass polyphenylene ether resin material that has a second number average molecular mass and is modified with a bisphenol functional group, wherein the second number average molecular mass is less than the first number average molecular mass; performing a nitration process which includes: carrying out a nitration reaction of the low molecular mass polyphenylene ether resin material, so that two ends of a polymer chain of the low molecular mass polyphenylene ether resin material are respectively modified with two nitro functional groups; and performing a hydrogenation process which includes: carrying out a hydrogenation reaction of the low molecular mass polyphenylene ether resin material that contains the polymer chain having the two ends respectively modified with the two nitro functional groups, wherein the low molecular mass polyphenylene ether resin material which contains the polymer chain having the two ends respectively modified with the two amino functional groups”, the polyphenylene ether resin modified with the functional groups has great compatibility and processability. At the same time, the polyphenylene ether resin can retain its excellent electrical properties (e.g., insulation, acid and alkali resistance, dielectric constant, and dielectric dissipation factor). Accordingly, the polyphenylene ether resin can be used to effectively improve electrical characteristics of the circuit board, especially when being applied to a substrate material of a high-frequency circuit board of the 5G technology.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a flowchart of a method for producing a polyphenylene ether resin modified with two amino functional groups according to an embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

Most conventional epoxy resin hardeners are bisamine epoxy resin hardeners, which have high reactivity, great reliability, and great stability.

However, the conventional epoxy resin hardeners have a high dielectric constant and a high dielectric dissipation factor. Therefore, the conventional epoxy resin hardeners, when being applied to the substrate material of a circuit board (e.g., a high-frequency circuit board using the 5G technology), cannot effectively improve electrical characteristics of the circuit board.

### Method for Producing Polyphenylene Ether Resin Modified with Two Amino Functional Groups

In response to the above-referenced technical inadequacies, the present disclosure provides a method for producing a polyphenylene ether resin modified with two amino functional groups.

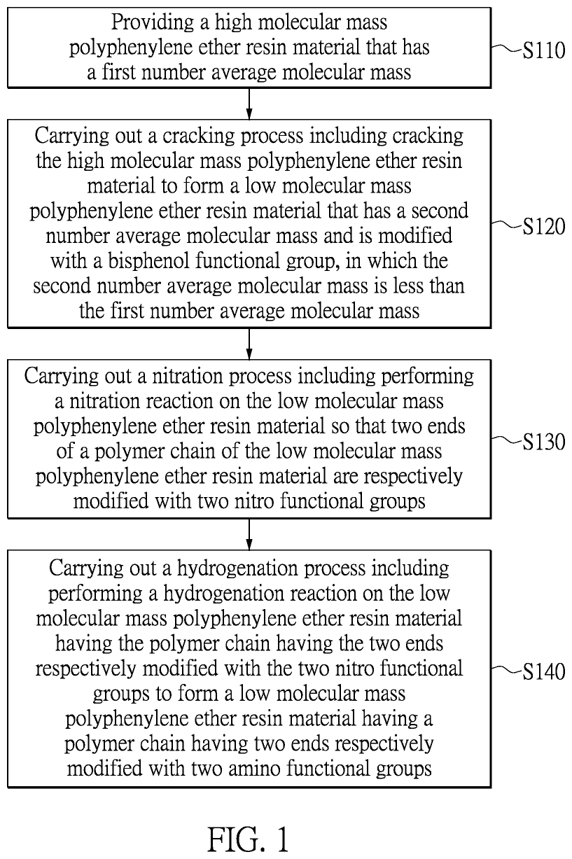

As shown in FIG. 1, the method for producing the polyphenylene ether resin modified with the two amino functional groups sequentially includes the following steps: step S110, step S120, step S130, and step S140. It should be noted that an order of each of the steps and actual ways of operation described in the present embodiment can be adjusted according to practical requirements, and the present embodiment is not limited thereto.

The step S110 includes: providing a high molecular mass polyphenylene ether (PPE) resin material that has a first number average molecular mass.

In some embodiments of the present disclosure, the first number average molecular mass (Mn) of the high molecular mass polyphenylene ether resin material is not less than 18,000 and preferably not less than 20,000, but the present disclosure is not limited thereto.

The high molecular mass polyphenylene ether resin material has a structural formula as follows (1-1).

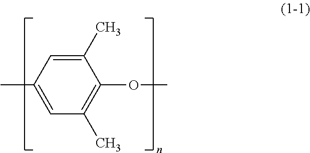

Here, n is an integer between 150 and 330 and preferably between 165 and 248.

It is worth mentioning that the polyphenylene ether resin material can also be called polyphenylene oxide (PPO). The polyphenylene ether resin material has excellent insulation, acid and alkali resistance, an excellent dielectric constant, and a low dielectric dissipation factor. Accordingly, the polyphenylene ether resin material has better electrical properties than epoxy resin materials, and the polyphenylene ether resin material is more suitable for use as an insulating substrate material for a high-frequency printed circuit board.

However, a commercially available polyphenylene ether resin material is an amorphous thermoplastic polymer, which has an excessive molecular mass (e.g., Mn≥18,000). The polyphenylene ether resin material with a large molecular mass has poor solubility in solvents. As a result, if there is not any treatment, the polyphenylene ether resin material has poor compatibility and processability, such that directly introducing or applying the polyphenylene ether resin material to the substrate material for the circuit board can be difficult.

Accordingly, many research and development activities are conducted to address the above-mentioned deficiencies, so as to improve the compatibility and the processability of the polyphenylene ether resin material and retain the excellent electrical properties of the polyphenylene ether resin material at the same time.

In order to achieve the above objectives, the polyphenylene ether resin modified with the two amino functional groups of the embodiment of the present disclosure can be provided by performing the following steps S120 to S140, and can effectively improve the compatibility and the processability of the polyphenylene ether resin material.

The step S120 is to perform a cracking process which includes: cracking the high molecular mass polyphenylene ether resin material to form a low molecular mass polyphenylene ether resin material that has a second number average molecular mass and is modified with a bisphenol functional group (that is, a low molecular mass PPE having phenolic end groups). The second number average molecular mass is less than the first number average molecular mass (that is, a number-average molecular mass of the polyphenylene ether resin material before cracking).

In some embodiments of the present disclosure, the second number average molecular mass (Mn) of the low molecular mass polyphenylene ether resin material is not greater than 12,000 and preferably not greater than 10,000, but the present disclosure is not limited thereto.

More specifically, the cracking process includes: reacting a bisphenol compound and the high molecular mass polyphenylene ether resin material having the first number average molecular mass (that is, the high molecular mass PPE) in a presence of a peroxide, so that the high molecular mass polyphenylene ether resin material is cracked to form the low molecular mass polyphenylene ether resin material having the second number average molecular mass that is less than the first number average molecular mass. A side of a polymer chain of the low molecular mass polyphenylene ether resin material is modified with the bisphenol functional group, and said low molecular mass polyphenylene ether resin material has a structural formula as follows (1-2).

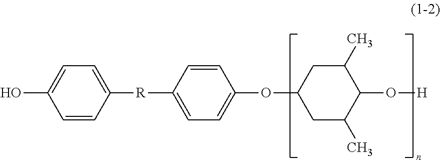

Here, R represents a chemical group that is located between two hydroxyphenyl functional groups of a bisphenol compound. For instance, as shown in Table 2 below, R can be a direct bond, methylene, ethylene, isopropylene, 1-methylpropyl, sulfone, or fluorene, but the present disclosure is not limited thereto.

Further, n is an integer between 3 and 25, inclusive, and preferably between 10 and 18. In some embodiments of the present disclosure, a number-average molecular mass (Mn) of the low molecular mass polyphenylene ether resin material is generally between 500 g/mol and 5,000 g/mol, preferably between 1,000 g/mol and 3,000 g/mol, and more preferably between 1,500 g/mol and 2,500 g/mol. In addition, a weight-average molecular weight (Mw) of the low molecular mass polyphenylene ether resin material is usually between 1,000 g/mol and 10,000 g/mol, preferably between 1,500 g/mol and 5,000 g/mol, and more preferably between 2,500 g/mol and 4,000 g/mol.

In some embodiments of the present disclosure, the bisphenol compound is at least one material selected from a group consisting of 4,4′-biphenol, bisphenol A, bisphenol B, bisphenol S, bisphenol fluorene, 4,4′-ethylene bisphenol, 4,4′-dihydroxydiphenylmethane, 3,5,3′,5′-tetramethyl-4,4′-dihydroxybiphenyl, and 2,2-bis (4-hydroxy-3,5-dimethylphenyl) propane. A material type of the bisphenol compound is shown in Table 1 below.

TABLE 1

| Item | Bisphenol compound | CAS number |
|---|---|---|
| 1 | 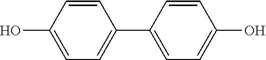 [SMILES: Oc1ccc(-c2ccc(O)cc2)cc1] | 92-88-6 (4,4′-biphenol) |
| 2 | 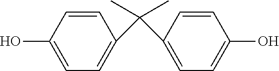 [SMILES: CC(C)(c1ccc(O)cc1)c1ccc(O)cc1] | 80-05-7 (Bisphenol A) |
| 3 | 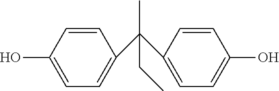 [SMILES: CCC(C)(c1ccc(O)cc1)c1ccc(O)cc1] | 77-40-7 (Bisphenol B) |
| 4 | 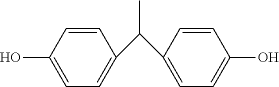 [SMILES: CC(c1ccc(O)cc1)c1ccc(O)cc1] | 2081-08-5 (4,4′-ethylene bisphenol) |
| 5 | 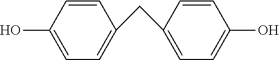 [SMILES: Oc1ccc(Cc2ccc(O)cc2)cc1] | 620-92-8 (4,4′-dihydroxydiphenylmethane) |
| 6 | 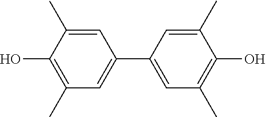 [SMILES: Cc1cc(-c2cc(C)c(O)c(C)c2)cc(C)c1O] | 2417-04-1 (3,5,3′,5′-tetramethyl-4,4′- dihydroxybiphenyl) |
| 7 | 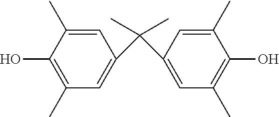 [SMILES: Cc1cc(C(C)(C)c2cc(C)c(O)c(C)c2)cc(C)c1O] | 5613-46-7 (2,2-bis(4-hydroxy-3,5- dimethylphenyl)propane) |
| 8 | 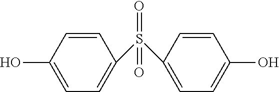 [SMILES: O=S(=O)(c1ccc(O)cc1)c1ccc(O)cc1] | 80-09-1 (Bisphenol S) |
| 9 | 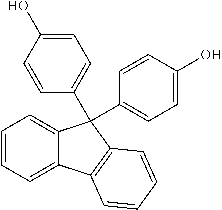 [SMILES: Oc1ccc(C2(c3ccc(O)cc3)c3ccccc3-c3ccccc32)cc1] | 3236-71-3 (Bisphenol Fluorene) |

The above-mentioned chemical group that is located between the two hydroxyphenyl functional groups of the bisphenol compound is shown in Table 2 below.

TABLE 2

| | | The chemical group located |
|---|---|---|
| | | between the two hydroxyphenyl |
| | | functional groups of the bisphenol |
| Item | Bisphenol compound | compound |
| 1 | 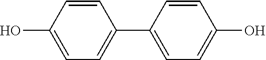 [SMILES: Oc1ccc(-c2ccc(O)cc2)cc1] | Direct bond |
| 2 | 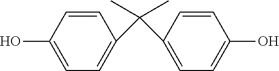 [SMILES: CC(C)(c1ccc(O)cc1)c1ccc(O)cc1] | Isopropylidene |
| 3 | 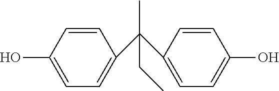 [SMILES: CCC(C)(c1ccc(O)cc1)c1ccc(O)cc1] | 1-methylpropyl (or, 2-butyl) |
| 4 | 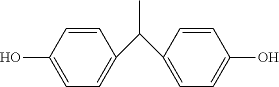 [SMILES: CC(c1ccc(O)cc1)c1ccc(O)cc1] | Ethylene |
| 5 | 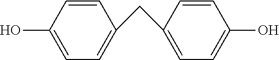 [SMILES: Oc1ccc(Cc2ccc(O)cc2)cc1] | Methylene |
| 6 | 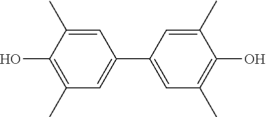 [SMILES: Cc1cc(-c2cc(C)c(O)c(C)c2)cc(C)c1O] | Direct bond |
| 7 | 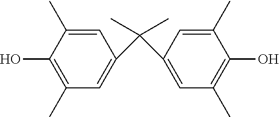 [SMILES: Cc1cc(C(C)(C)c2cc(C)c(O)c(C)c2)cc(C)c1O] | Isopropylidene |
| 8 | 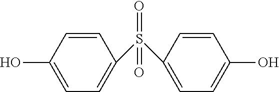 [SMILES: O=S(=O)(c1ccc(O)cc1)c1ccc(O)cc1] | Sulfone |
| 9 | 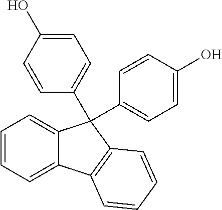 [SMILES: Oc1ccc(C2(c3ccc(O)cc3)c3ccccc3-c3ccccc32)cc1] | Fluorene |

In some embodiments of the present disclosure, a material type of the peroxide is at least one selected from a group consisting of azobisisobutyronitrile, benzyl peroxide, and dicumyl peroxide. The material type of the peroxide is shown in Table 3 below.

TABLE 3

| Item | Peroxide | CAS number |
|---|---|---|
| 1 | 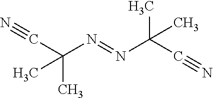 | 78-67-1 (Azobisiso- butyronitrile) |
| 2 | 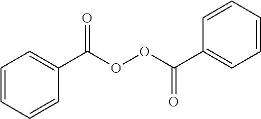 [SMILES: O=C(OOC(=O)c1ccccc1)c1ccccc1] | 94-36-0 (Benzyl peroxide) |
| 3 | 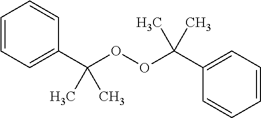 [SMILES: CC(C)(OOC(C)(C)c1ccccc1)c1ccccc1] | 80-43-3 (Dicumyl peroxide) |

The step S130 is to perform a nitration process which includes: carrying out a nitration reaction of the low molecular mass polyphenylene ether resin material so that two ends of a polymer chain of the low molecular mass polyphenylene ether resin material are respectively modified with two nitro functional groups (that is, a terminal nitro PPE). The low molecular mass polyphenylene ether resin material that contains the polymer chain having the two ends respectively modified with the two nitro functional groups has the structural formula as follows (1-3).

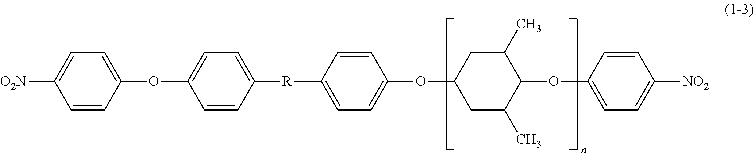

More specifically, the nitration process includes carrying out the nitration reaction of a 4-halonitrobenzene material and the low molecular mass polyphenylene ether resin material that is cracked and modified with the bisphenol functional group in an alkaline environment so that the two ends of the polymer chain of the low molecular mass polyphenylene ether resin material are respectively modified with the two nitro functional groups.

Through the 4-halonitrobenzene material and the low molecular mass polyphenylene ether resin material having the nitration reaction in the alkaline environment, negatively-charged oxygen ions are formed at the two ends of the polymer chain of the low molecular mass polyphenylene ether resin material. 4-halonitrobenzene is easily attacked by the negatively-charged oxygen ions, so that halogen of the 4-halonitrobenzene can be removed and the two ends of the polymer chain of the low molecular mass polyphenylene ether resin material can be further modified with two nitrophenyl functional groups. That is, through the above-mentioned reaction mechanism, the two ends of the polymer chain of the low molecular mass polyphenylene ether resin material can be respectively modified with the two nitrophenyl functional groups.

In some embodiments of the present disclosure, the nitration process allows the nitration reaction of the low molecular mass polyphenylene ether resin material to be carried out in the alkaline environment, the alkaline environment having a pH value between 8 and 14. Preferably, the pH value is between 10 and 14, but the present disclosure is not limited thereto.

In some embodiments of the present disclosure, the 4-halonitrobenzene material has a structural formula as shown below, and a material type of the 4-halonitrobenzene material is as shown in Table 4 below.

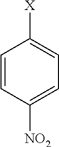

Here, X is the halogen and preferably fluorine element (F), chlorine element (Cl), bromine element (Br), or iodine element (I).

TABLE 4

| Item | 4-halonitrobenzene | CAS number |
|---|---|---|
| 1 | 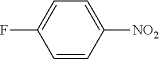 | 350-46-9 |
| 2 | 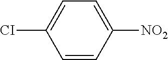 | 100-00-5 |
| 3 | 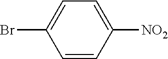 | 586-78-7 |
| 4 | 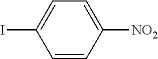 | 636-98-6 |

The step S140 is to perform a hydrogenation process which includes: carrying out a hydrogenation reaction of the low molecular mass polyphenylene ether resin material that contains the polymer chain having the two ends respectively modified with the two nitro functional groups to form a low molecular mass polyphenylene ether resin material that contains a polymer chain having two ends respectively modified with two amino functional groups. This low molecular mass polyphenylene ether resin material has the structural formula as follows (1-4).

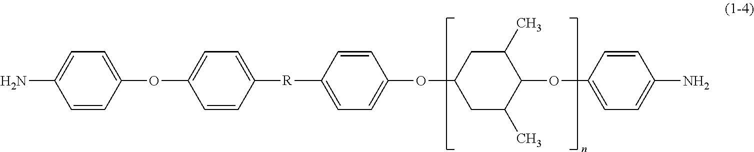

More specifically, the hydrogenation process includes carrying out the hydrogenation reaction of a hydrogenation solvent and the low molecular mass polyphenylene ether resin material that contains the polymer chain having the two ends respectively modified with the two nitro functional groups. A material type of the hydrogenation solvent is at least one material selected from a group consisting of dimethylacetamide (DMAC, CAS No. 127-19-5), tetrahydrofuran (THF, CAS No. 109-99-9), toluene (CAS No. 108-88-3), and isopropanol (CAS No. 67-63-0).

In some embodiments of the present disclosure, the dimethylacetamide is used as the hydrogenation solvent, so that the hydrogenation process can achieve an excellent hydrogenation conversion rate (e.g., the hydrogenation conversion rate being greater than 99%). However, the present disclosure is not limited thereto.

It is worth mentioning that parameters that control the hydrogenation conversion rate include: (1) selection of solvents and a mixing ratio of the solvents, (2) addition of a catalyst, (3) hydrogenation reaction time, (4) hydrogenation reaction temperature, and (5) hydrogenation reaction pressure.

The material type of the hydrogenation solvent is as shown in Table 5 below.

TABLE 5

| Item | Hydrogenation solvent | CAS number |
|---|---|---|
| 1 | 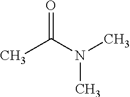 | 127-19-5 (N,N-dimethylacetamide) |
| 2 | 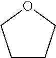 | 109-99-9 (Tetrahydrofuran) |
| 3 | 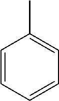 | 108-88-3 (Toluene) |
| 4 | 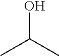 | 67-63-0 (Isopropyl alcohol) |

Through the above-mentioned series of material modification processes, the high molecular mass polyphenylene ether resin material can be cracked into the low molecular mass polyphenylene ether resin material, a molecular structure of the low molecular mass polyphenylene ether resin material can be modified with the bisphenol functional group, and the two ends of the polymer chain of the low molecular mass polyphenylene ether resin material are further modified with the two amino functional groups.

Accordingly, the modified polyphenylene ether resin has great compatibility and processability, and the excellent electrical properties (such as insulation, acid and alkali resistance, dielectric constant, and dielectric dissipation factor) of the polyphenylene ether resin can be retained at the same time. In this way, the polyphenylene ether resin can be used to effectively improve the electrical characteristics of the circuit board, especially when being applied to the substrate material of the high-frequency circuit board of the 5G technology.

In some embodiments of the present disclosure, after the above-mentioned modified polyphenylene ether resin material is introduced into the substrate material for the circuit board, the substrate material for the circuit board can have a low dielectric constant (e.g., Dk=3.5 to 4.0) and a low dielectric dissipation factor (e.g., Df=0.002 to 0.01) at a high frequency (e.g., a millimeter wave ranging from 10 GHz to 100 GHz). In addition, the substrate material for the circuit board can have a high glass transition temperature (e.g., ≥230° C.), and a peel strength that is not less than 5 lb/in.

Speaking overall, the purpose of the embodiments of the present disclosure is to modify terminal structures of the polymer chain of the polyphenylene ether resin material. The method sequentially includes: cracking and modifying the polyphenylene ether resin material with the bisphenol functional group; performing a nitration grafting between the 4-halonitrobenzene material and the polyphenylene ether resin material that is depolymerized and modified with the bisphenol functional group; enabling the polyphenylene ether resin material that is subjected to the nitration grafting to have the hydrogenation reaction; and modifying the polyphenylene ether resin material that is subjected to the hydrogenation reaction with the benzoxazine. Accordingly, an overall molecular mass of the polyphenylene ether resin material can be reduced, and the ends of the polymer chain of the polyphenylene ether resin material can have benzoxazine functional groups that are capable of generating a self-crosslinking reaction.

A molecular structure of the above-mentioned modified polyphenylene ether resin material has no polar group, so that problems associated with the compatibility and processability of the polyphenylene ether resin material can be solved. At the same time, the dielectric constant and the dielectric dissipation factor of the above-mentioned modified polyphenylene ether resin material are significantly reduced.

The above-mentioned modified polyphenylene ether resin material can be used as a high-frequency and low-dielectric ammonia hardener, and in addition to being able to react with the epoxy resin, it can also be used with resin materials, such as bismaleimide resin, benzoxazine resin, and polyimide resin to form other novel compounds with application value.

### Polyphenylene Ether Resin Modified with Two Amino Functional Groups

The embodiment of the present disclosure also provides a polyphenylene ether resin modified with two amino functional groups, which is produced by the method mentioned above. However, the present disclosure is not limited thereto. The polyphenylene ether resin modified with the two amino functional groups can also be formed by other suitable modification methods. More specifically, the polyphenylene ether resin modified with the two amino functional groups has a structural formula as follows:

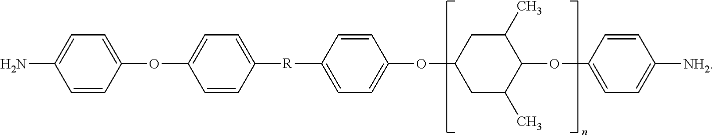

Here, R represents a chemical group that is located between two hydroxyphenyl functional groups of a bisphenol compound, and n is an integer between 3 and 25 (preferably between 10 to 18), inclusive.

### Substrate Material for Circuit Board

The embodiment of the present disclosure also provides a substrate material for a circuit board, and the substrate material for the circuit board includes at least 20 wt % of the polyphenylene ether resin modified with the two amino functional groups mentioned above. The substrate material for the circuit board has a dielectric constant that is between 3.5 and 4.0, a dielectric dissipation factor that is between 0.003 and 0.005, a glass transition temperature that is not less than 230° C., and a peel strength that is not less than 5 lb/in.

### Experimental Data and Results Discussion

Hereinafter, a more detailed description will be provided with reference to Examples 1 to 3 and a Comparative Example. However, the examples below are provided only to aid in understanding of the present disclosure, and are not to be construed as limiting the scope of the present disclosure.

### Example 1

A cracked low molecular mass PPE (Mn=500) is put in a dimethylacetamide solvent for dissolution, and potassium carbonate and tetrafluoronitrobenzene are added. The dimethylacetamide solvent, the cracked low molecular mass PPE, the potassium carbonate, and the tetrafluoronitrobenzene are heated to reach a temperature of 140° C. and react for 8 hours before being cooled to a room temperature, and then are filtered to remove solids therein. A precipitation is carried out by using methanol/water, so as to obtain a precipitation product (i.e., PPE-NO₂). The product (PPE-NO₂) is put in the dimethylacetamide solvent again to have a hydrogenation reaction at 90° C. for 8 hours, so that a PPE-NH₂ product is formed.

### Example 2

A cracked low molecular mass PPE (Mn=1,400) is put in a dimethylacetamide solvent for dissolution, and potassium carbonate and tetrafluoronitrobenzene are added. The dimethylacetamide solvent for dissolution, the cracked low molecular mass PPE, the potassium carbonate, and the tetrafluoronitrobenzene are heated to reach a temperature of 140° C. and react for 8 hours before being cooled to a room temperature, and then are filtrated to remove solids therein. A precipitation is carried out by using methanol/water, so as to obtain a precipitation product (i.e., PPE-NO₂); The product (PPE-NO₂) is put in the dimethylacetamide solvent again to have a hydrogenation reaction at 90° C. for 8 hours, so that a PPE-NH₂ product is formed.

### Example 3

A cracked low molecular mass PPE (Mn=1,800) is put in a dimethylacetamide solvent for dissolution, and potassium carbonate and tetrafluoronitrobenzene are added. The dimethylacetamide solvent, the cracked low molecular mass PPE, the potassium carbonate, and the tetrafluoronitrobenzene are heated to reach a temperature of 140° C. and react for 8 hours before being cooled to a room temperature, and then are filtered to remove solids therein. A precipitation is carried out by using methanol/water, so as to obtain a precipitation product (i.e., PPE-NO₂). The product (PPE-NO₂) is put in the dimethylacetamide solvent again to have a hydrogenation reaction at 90° C. for 8 hours, so that a PPE-NH₂ product is formed.

### Comparative Example

A commercially available epoxy is used as a comparative example.

Next, the resin materials prepared in Examples 1 to 3 are introduced into the substrate material for the circuit board, and tests of their physicochemical properties (such as dielectric constant (Dk), dielectric dissipation factor (Df), glass transition temperature (Tg), and peel strength) are carried out. The relevant test methods are described below, and the relevant test results are listed in Table 1.

TABLE 1
Preparation Conditions and Test Results

| | | Example | Example | Example | Comparative |
|---|---|---|---|---|---|
| Item | | 1 | 2 | 3 | Example |
| Molecular mass of cracked | | Mn = | Mn = | Mn = | commercially |
| low molecule PPE used in | | 500 | 1,400 | 1,800 | available |
| the preparation of PPE-NH2 | | | | | epoxy |
| Test | Dielectric Constant (Dk) | 3.6 | 3.5 | 3.5 | 3.7 |
| results | Dielectric dissipation | 0.0045 | 0.0042 | 0.0041 | 0.0046 |
| | factor (Df) | | | | |
| | Dk/Df | 800 | 833.33 | 853.65 | 804.34 |
| | Glass Transition | 281.1 | 276.8 | 272 | 284.5 |
| | Temperature | | | | |
| | Peel Strength | 3.1 | 3.6 | 3.9 | 3.2 |

### Discussion of Test Results

As shown in the test results of Examples 1 to 3 and Comparative Example, when the molecular mass of the PPE is lower, a main chain PPE in the PPE-BX is shorter, and the PPE has low dielectric properties (low Dk and low Df). Therefore, a PPE structure chain is shorter, and an electrical performance is poor. Nevertheless, the electrical properties of a structure PPE-NH2 are greater than those of the commercially available epoxy.

### Beneficial Effects of the Embodiments

In conclusion, in the polyphenylene ether resin modified with the two amino functional groups, the method for producing the same, and the substrate material for the circuit board provided by the present disclosure, by virtue of “providing a high molecular mass polyphenylene ether resin material that has a first number average molecular mass; performing a cracking process which includes: cracking the high molecular mass polyphenylene ether resin material to form a low molecular mass polyphenylene ether resin material that has a second number average molecular mass and is modified with a bisphenol functional group, wherein the second number average molecular mass is less than the first number average molecular mass; performing a nitration process which includes: carrying out a nitration reaction of the low molecular mass polyphenylene ether resin material, so that two ends of a polymer chain of the low molecular mass polyphenylene ether resin material are respectively modified with two nitro functional groups; and performing a hydrogenation process which includes: carrying out a hydrogenation reaction of the low molecular mass polyphenylene ether resin material that contains the polymer chain having the two ends respectively modified with the two nitro functional groups, wherein the low molecular mass polyphenylene ether resin material which contains the polymer chain having the two ends respectively modified with the two amino functional groups”, the polyphenylene ether resin modified with the functional groups has great compatibility and processability. At the same time, the polyphenylene ether resin can retain its excellent electrical properties (e.g., insulation, acid and alkali resistance, dielectric constant, and dielectric dissipation factor). Accordingly, the polyphenylene ether resin can be used to effectively improve electrical characteristics of the circuit board, especially when being applied to a substrate material of a high-frequency circuit board of the 5G technology.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A method for producing a polyphenylene ether resin, comprising:
providing a high molecular mass polyphenylene ether resin material that has a first number average molecular mass;
performing a cracking process which includes: cracking the high molecular mass polyphenylene ether resin material to form a low molecular mass polyphenylene ether resin material that has a second number average molecular mass and is modified with a bisphenol functional group, wherein the second number average molecular mass is less than the first number average molecular mass;
performing a nitration process which includes: carrying out a nitration reaction of the low molecular mass polyphenylene ether resin material, so that two ends of a polymer chain of the low molecular mass polyphenylene ether resin material are respectively modified with two nitro functional groups; and
performing a hydrogenation process which includes: carrying out a hydrogenation reaction of the low molecular mass polyphenylene ether resin material that contains the polymer chain having the two ends respectively modified with the two nitro functional groups, wherein the low molecular mass polyphenylene ether resin material which contains the polymer chain having the two ends respectively modified with the two amino functional groups has a structural formula as follows: 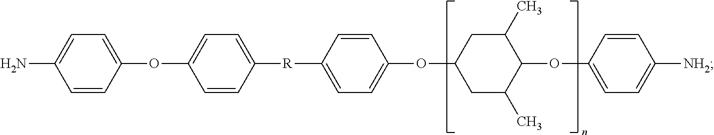
wherein R represents a chemical group that is located between two hydroxyphenyl functional groups of a bisphenol, and n is an integer between 3 and 25, inclusive.

2. The method according to claim 1, wherein the first number average molecular mass (Mn) of the high molecular mass polyphenylene ether resin material is not less than 18,000, and the second number average molecular mass of the low molecular mass polyphenylene ether resin material is not greater than 12,000.

3. The method according to claim 1, wherein the cracking process includes: reacting the bisphenol compound with the high molecular mass polyphenylene ether resin material having the first number average molecular mass in a presence of peroxide, so that the high molecular mass polyphenylene ether resin material is cracked to form the low molecular mass polyphenylene ether resin material having the second number average molecular mass, and wherein a side of the polymer chain of the low molecular mass polyphenylene ether resin material is modified with the bisphenol functional group.

4. The method according to claim 3, wherein the bisphenol compound is at least one material selected from a group consisting of 4,4′-biphenol, bisphenol A, bisphenol B, bisphenol S, bisphenol fluorene, 4,4′-ethylene bisphenol, 4,4′-dihydroxydiphenylmethane, 3,5,3′,5′-tetramethyl-4,4′-dihydroxybiphenyl, and 2,2-bis (4-hydroxy-3,5-dimethylphenyl) propane, and wherein a material type of the peroxide is at least one selected from a group consisting of azobisisobutyronitrile, benzyl peroxide, and dicumyl peroxide.

5. The method according to claim 1, wherein the nitration process includes: carrying out the nitration reaction of a 4-halonitrobenzene material with the low molecular mass polyphenylene ether resin material that is cracked and modified with the bisphenol functional group in an alkaline environment, so that the two ends of the polymer chain of the low molecular mass polyphenylene ether resin material are respectively modified with the two nitro functional groups.

6. The method according to claim 5, wherein the nitration process allows the nitration reaction of the low molecular mass polyphenylene ether resin material to be carried out in the alkaline environment, the alkaline environment having a pH value between 8 and 14.

7. The method according to claim 1, wherein the hydrogenation process includes: carrying out the hydrogenation reaction of a hydrogenation solvent with the low molecular mass polyphenylene ether resin material that contains the polymer chain having the two ends respectively modified with the two nitro functional groups, and wherein a material type of the hydrogenation solvent is at least one material selected from a group consisting of dimethylacetamide, tetrahydrofuran, toluene, and isopropanol.

8. The method according to claim 7, wherein the hydrogenation solvent adopts the dimethylacetamide to carry out the hydrogenation reaction.

9. A polyphenylene ether resin modified with two amino functional groups, which is suitable for use as a substrate material for a circuit board comprising a structural formula as follows: 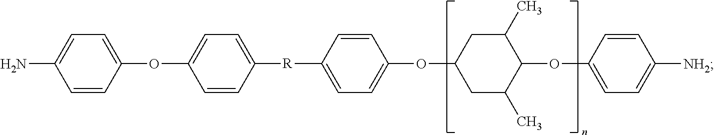
wherein R represents a chemical group that is located between two hydroxyphenyl functional groups of a bisphenol compound, and n is an integer between 3 and 25, inclusive.

10. A substrate material for a circuit board, comprising at least 20 wt % of the polyphenylene ether resin modified with the two amino functional groups as claimed in claim 9, wherein the substrate material for the circuit board has a dielectric constant (Dk) that is between 3.5 and 4.0, a dielectric dissipation factor (Df) that is between 0.003 and 0.005, a glass transition temperature that is not less than 230° C., and a peel strength that is not less than 5 lb/in.
